(19) United States
(12) Patent Application Publication
(10) Pub. No.: US 2012/0054563 A1
(43) Pub. Date: Mar. 1, 2012

(54) System and Method for Enabling Portable Diagnostics in a Configurable Device

(75) Inventor: Wael William Diab, San Francisco, CA (US)

(73) Assignee: Broadcom Corporation, Irvine, CA (US)

(21) Appl. No.: 12/873,371

(22) Filed: Sep. 1, 2010

(51) Int. Cl. G01R 31/28; G06F 11/22

(52) U.S. Cl. 714/712; 714/E11.145

(57) ABSTRACT

A system and method for enabling portable diagnostics in a configurable device. Physical layer device technology can be implemented into a configurable device (e.g., handheld device) to perform diagnostics. The configurable device can be enabled for diagnostics through an authentication module that performs an authentication and/or licensing function. Diagnostic information (e.g., channel characteristics, data analysis, traffic analysis, packet analysis, bit analysis, etc.) can be displayed on a display of the configurable device to assist field personnel.

### BACKGROUND

1. Field of the Invention

The present invention relates generally to cable diagnostics and, more particularly, to a system and method for enabling portable diagnostics in a configurable device.

2. Introduction

Effective troubleshooting of cable installations in the field will typically require complementing efforts between the field technician and the diagnostic tools made available to the field technician. In addition to the suitability of the diagnostic tool in performing a particular cable test, the usability of the diagnostic tool is also a key factor in determining its ultimate benefit. Here, the performance of even the most experienced field technician would be dependent on the diagnostic tools available to help locate and diagnose fault conditions. As would be appreciated various field conditions can exist when diagnosing cable installations.

In reducing costs of installation, diagnosis, and repair it is critical that the field technicians are equipped with cost-effective, easy-to-use diagnostic tools. These diagnostic tools should accommodate the profile of field technicians that are highly mobile in and between field diagnostic events. What is needed therefore is a cable diagnostic tool that is portable and that can incorporate cable diagnostic functions in a cost-effective manner.

### SUMMARY

A system and/or method for enabling portable diagnostics in a configurable device, substantially as shown in and/or described in connection with at least one of the figures, as set forth more completely in the claims.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates an embodiment of a configurable diagnostic device.

FIG. 2 illustrates an embodiment of a physical layer device in a configurable diagnostic device.

FIG. 3 illustrates a flowchart of a process of the present invention.

### DETAILED DESCRIPTION

Various embodiments of the invention are discussed in detail below. While specific implementations are discussed, It should be understood that this is done for illustration purposes only. A person skilled in the relevant art will recognize that other components and configurations may be used without parting from the spirit and scope of the invention.

Cable testing in an installation environment is a crucial activity performed by field technicians. Ensuring the integrity of a cabling installation is a key factor in the installation of communication links between various forms of network equipment (e.g., receivers, set top boxes, switches, servers, etc.). The effectiveness of diagnostic tools employed by the field technicians has a direct impact on the cost structure associated with the installation and maintenance activity.

Conventional diagnostic tools include specialized cable tester devices that provide lab-like accuracy in their sets of measurements. Examples of such diagnostic measurements can include attenuation (insertion loss), near end crosstalk (NEXT), far end crosstalk (FEXT), cable length, propagation delay, etc. For these specialized diagnostic devices costs can also be significant.

In general, the high cost of these specialized diagnostic devices may not be justified in an installation environment. Installation environments do not require lab-precision accuracy in their measurements. For example, cable testers in an installation environment are often used simply to detect attenuation on a cable. Moreover, cable testers in an installation environment often are not used to measure long cable runs. This is especially true in a home network environment where the cables being tested are short-run links that are well within the maximum lengths imposed by worst-case signal degradation scenarios.

In the present invention, it is recognized that the specialized diagnostic devices currently in use do not represent a value proposition for the installation company or the field technicians. The cost is simply not justified for using diagnostic devices that are overdesigned for their intended use.

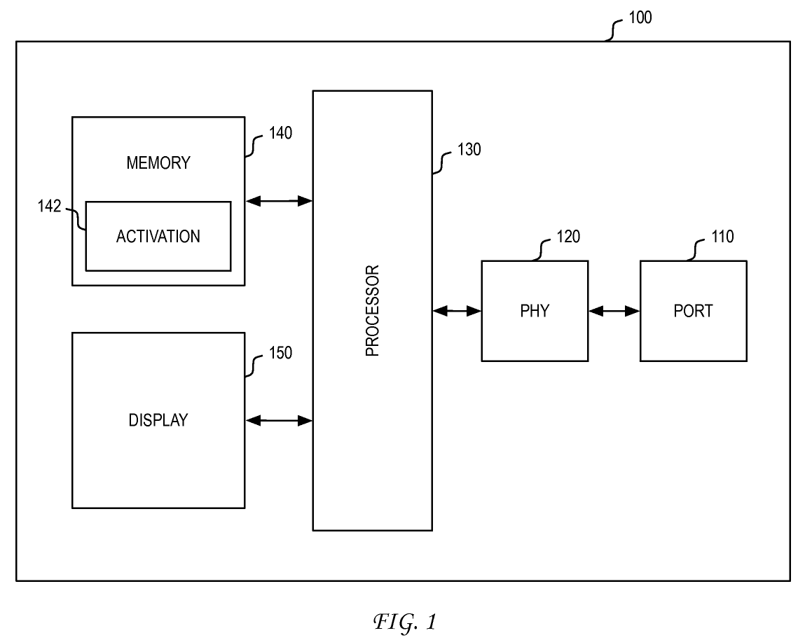

As will be described in greater detail below, a configurable diagnostic device can be provided that has sufficient diagnostic capabilities for the needs of a field environment, yet for significantly reduced cost. FIG. 1 illustrates an example of an embodiment of a configurable diagnostic device according to the present invention.

As illustrated, configurable diagnostic device 100 includes port 110 for receiving a cable connector. In one example, port 110 can be designed to receive a RJ45 connector. In another example, port 110 can be designed to receive an adapter (e.g., dongle) that enables coupling of a RJ45 connector to port 110. In another examples, other types of connectors and/or technologies can be supported such as MoCA, coax, DSL, BroadReach Ethernet, etc. As would be appreciated, the principles of the present invention are not dependent on a particular form factor of port 110. In general, port 110 can be designed to facilitate a connection to a particular type of cabling (e.g., copper, fiber optic, coax, etc.) and connector to physical layer device (PHY) module 120.

In general, a PHY is a Layer 1 device that can be designed to connect a Layer 2 data link layer device (e.g., media access control (MAC) device) to a physical medium coupled to port 110. In an example implementation of a PHY, the PHY can include a physical coding sublayer (PCS) that encodes and decodes the data that is transmitted and received, and a physical medium dependent (PMD) layer that includes a transceiver for the physical medium. In combination, the PHY can include suitable logic, circuitry, and/or code that enables transmission and reception of data with a link partner. In this process, the PHY can be configured to handle physical layer requirements, which include, but are not limited to, packetization, data transfer and serialization/deserialization (SERDES).

A PHY can be designed to perform channel diagnostics that examine one or more properties of the communication channel. Various properties of the communication channel can be examined, such as whether or not a link is active, insertion loss, cross talk, the length of the communication cable, the type of communication cable, the existence and/or location of a connector or fault in the cable, etc. An example of the use of a PHY to perform channel diagnostics is included in U.S. Pat. No. 7,664,972, entitled “System and Method for Controlling Power Delivered to a Powered Device Based on Cable Characteristics,” which is incorporated herein by reference in its entirety.

Conventionally, the properties of the communication channel that are examined can be used for channel equalization in enabling the PHY to optimize its coefficients for transmission over the particular communication channel to which it is connected. In accordance with the present invention, the properties of the communication channel that are determined by the PHY can be used in a cable diagnostics report of the configurable diagnostic device.

Here, it should be noted that PHY module 120 need not be a full-featured PHY such as that used to connect a Layer 2 data link layer device (e.g., MAC) to a physical medium in a link between peer devices. As such, PHY module 120 can be embodied as a reduced-functionality PHY that incorporates at least the PHY functionality focused on channel diagnostics. As PHY module 120 in configurable cable diagnostic device 100 need not communicate with a link partner, much of the data communication functionality (e.g., PHY/MAC interface) can be removed or left inactive. Of significance is that the PHY channel diagnostic functionality in PHY module 120 represents a mature and increasingly low-cost technology that can be incorporated into configurable cable diagnostic device 100.

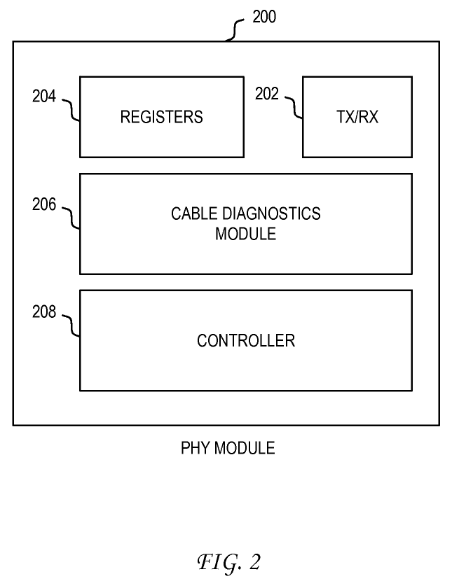

FIG. 2 illustrates an example embodiment of a PHY module that is incorporated into configurable diagnostic device 100. As illustrated, PHY module 200 includes transmit/receive (TX/RX) module 202, registers 204, cable diagnostic module 206, and controller 208.

In general, TX/RX module 202 facilitates a communication interface between cable diagnostic module 206 and the signals carried on the communication cable coupled to the diagnostic device port. In one embodiment, cable diagnostic module 206 performs the cable diagnostics non-invasively. This is in contrast to conventional cable testers that use a direct line tap.

Further, in various embodiments, cable diagnostic module 206 can perform the cable diagnostics independently or in cooperation with an active data communication process that is occurring with a device on the other end of the communication cable, or with a remote device at a servicing company. As would be appreciated, the specific mechanism and corresponding method by which cable diagnostic module 206 operates in the context of a cooperative cable diagnostic would be implementation dependent.

In general, cable diagnostics performed by cable diagnostics module 206 are performed under the control of controller 208. Cable diagnostics module 206 can be designed to generate and transmit a signal (e.g., pulses) into the communication cable coupled to the diagnostic device port, and to measure a return or reflected signal received by TX/RX module 202. Signals received by TX/RX module 202 are then processed by cable diagnostic module 206 to determine various cabling parameters reflective of communication channel characteristics.

A simple example of a cabling parameter that can be identified is whether a communication channel is active. This can be determined by whether PHY module 200 detects any link energy on the patch panel port.

In another example, PHY module 200 can determine a cable length through time-domain reflectometry (TDR), which relies on the transmission of a pulse into the communication cable and the measurement of returned reflections of the transmitted pulse. The cable length or a distance to a cable fault can be determined from the time difference between the transmitted and reflected pulse. Cable failures and the location of such failures can be detected using TDR.

In yet another example, PHY module 200 measurements can be used to determine a type of cabling (e.g., Category 5, 6, 7, etc. Ethernet cabling) that is coupled to the patch panel port. As described in greater detail in U.S. Pat. No. 7,664,972, entitled “System and Method for Controlling Power Delivered to a Powered Device Based on Cable Characteristics,” which is incorporated herein by reference in its entirety, PHY measurements such as crosstalk and insertion loss can be used to determine a type of structured Ethernet cabling.

The measurements taken by PHY module 200 can be stored in memory registers 204. The information stored in memory registers 204 can then be retrieved by processor 130 of configurable cable diagnostic device 100.

It is a feature of the present invention that configurable cable diagnostic device 100 also includes an activation module. This activation module is designed to perform an authentication and/or licensing function that controls the activation of PHY module 120.

In one embodiment, configurable cable diagnostic device 100 can be embodied as a handheld device such as a smart phone or other portable device. This handheld device can be a mainstream consumer device, whose cable diagnostic functionality can be initially inaccessible to the diagnostic purposes of the user of the handheld device (e.g., tablet device that has a built-in RJ45 port). As this diagnostic functionality can potentially disrupt data communication on a shared medium (e.g., passive optical network (PON), coax, etc.) or potentially damage communication equipment on the other end, access and use of such diagnostic functionality should be controlled.

For this reason, configurable cable diagnostic device 100 can also be designed to include an activation module. This activation module can perform an authentication and/or licensing function that effectively controls which device and/or user operator can effectively access the cable diagnostic functionality. More generally, the activation module can be designed to control access to services that are based on the cable diagnostics function of the cable diagnostic device.

In one embodiment, the activation module is implemented as software activation module 142 that is stored in memory 140. This activation module 142 can represent software code that is designed to run as a software application that controls the configuration of cable diagnostic device 100 as a usable diagnostic device.

For example, a software diagnostic application can be designed to initially condition the access to PHY module 120 on the acquisition of an appropriate license. As would be appreciated, the license can be a device license and/or a user license. Once the license is obtained, actual usage of the cable diagnostic capability of PHY module 120 can be further conditioned on an authentication process that authenticates the device and/or the user. This authentication can be designed to ensure that unauthorized usage of PHY module 120 is prevented. For example, the authentication can be designed to prevent the usage of a PHY module that has been modified or otherwise compromised in some manner.

To illustrate the usage of the activation module, consider a scenario where a servicing company enlists hundreds of field technicians to use such configurable cable diagnostic devices. When the configurable cable diagnostic devices (e.g., company issued phone or tablet) are assigned to the individual field technicians, they can be provided with the appropriate device and/or user license. Such licenses can then permit the field technician with access to the cable diagnostic functionality of the device. Should a particular field technician be fired, the relevant license can then be revoked.

In general, the control of the licenses of the diagnostic devices can support various usage scenarios. For example, if the PHY module is incorporated in a widely available consumer device, then the cable diagnostic functionality can potentially be accessed by a company's customer in self-diagnosing an installation. In this scenario, the company can selectively activate/deactivate the cable diagnostic functionality remotely using the activation module. Results can be delivered by the customer to a remote company location for off-line analysis or on-line interactive analysis, or can be displayed on display 150 for the purposes of the customer and/or company.

The incorporation of an activation module in the cable diagnostic device is designed to provide a configurable aspect to the cable diagnostic device. This is in contrast to conventional cable tester devices that are dedicated, overdesigned devices. By incorporating the low-cost PHY functionality into a handheld device such as a consumer-level device, further reduction in field and maintenance costs can be achieved through the selective enlistment of end users/customers as field diagnostic technicians.

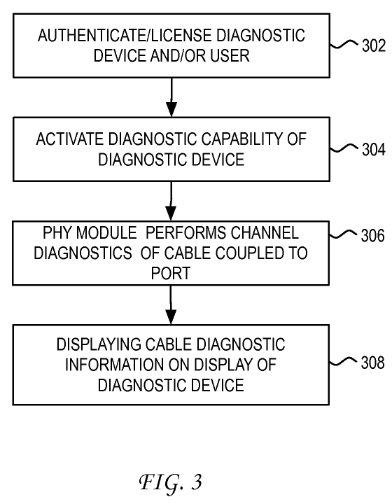

To further illustrate the configurable functionality of the present invention, reference is now made to the flowchart of FIG. 3. As illustrated, the process begins at step 302 where an activation module in a configurable cable diagnostic device is accessed. As noted above, this activation module can be a software application that can be designed to obtain the necessary authentication/licensing information for the device and/or user. As such, the authentication/licensing information can be obtained from user input, transparently from the device itself (e.g., memory access), or from communication with a remote device (e.g., server). As would be appreciated, various forms of authentication/licensing information can be used without departing from the scope of the present invention.

After the activation module authenticates/licenses the device and/or the user, the activation module can then activate the diagnostic capability of the cable diagnostic device at step 304. This activation represents a type of configurability, for example, as it is designed to transform the device in functionality. This is particularly noteworthy when considering the transformation of a general purpose device (e.g., smart phone) into a device having access to specialized cable diagnostic functionality.

Once the cable diagnostic functionality is activated, the PHY module in the cable diagnostic device can then perform one or more channel diagnostics of the communication cable coupled to the port. In one embodiment, control of the one or more diagnostics functions can be effected through a user interface that is presented on the display of the diagnostic device. In various example, the user interface can be designed for interaction with the user effecting control and/or a remote location that is interactively involved in the channel diagnostics. In one example, the authentication/license for the device and/or the user can be bound to a particular network device (e.g., home gateway, optical network terminal, customer premises equipment, etc.) that is associated with the communication cable being monitored.

Once the channel diagnostics are completed, the results can then be displayed on the display screen at step 308. This display can be suitable for a field technician that understands how to interpret the test results. For a customer that has been enlisted by the servicing company, the displayed results can be relayed manually to the servicing company or through an electronic transmission through a data network for interactive analysis.

Here, it should be noted that as the PHY module need not be a full-featured PHY, it can be incorporate significant diagnostic functionality with little additional cost. The inclusion of such a limited-functionality PHY into consumer-level devices can then be realized with a disproportionately large impact on field servicing options that can be presented to a servicing company.

It should also be noted that the cable diagnostics device can include PHY elements that support other testing functions beyond cable channel diagnostics. For example, the cable diagnostics device can be designed to support data, traffic, packet or bit testing as required. As would be appreciated, support for data, traffic, packet or bit testing can be based on PHY or higher layer elements that would be implementation dependent. Here, it is significant that such testing elements can be included in a portable diagnostic device that is configurable based on an activation module.

Further, it should be noted that the principles of the present invention can be applied to all types of cabling (e.g., copper, fiber optic, coax, etc.) and the various forms of connectors that support such cabling.

These and other aspects of the present invention will become apparent to those skilled in the art by a review of the preceding detailed description. Although a number of salient features of the present invention have been described above, the invention is capable of other embodiments and of being practiced and carried out in various ways that would be apparent to one of ordinary skill in the art after reading the disclosed invention, therefore the above description should not be considered to be exclusive of these other embodiments. Also, it is to be understood that the phraseology and terminology employed herein are for the purposes of description and should not be regarded as limiting.

What is claimed is:

1. A configurable cable diagnostic device, comprising:
a port that enables coupling of said cable diagnostic device to a communication cable;
a physical layer device that is coupled to said port, said physical layer device including a cable diagnostic module for analyzing characteristics of said communication cable coupled to said port, said cable diagnostic device having an initial operating state that prevents operation of said cable diagnostic module on said communication cable coupled to said port;
an activation module that is coupled to said physical layer device, said activation module receiving activation information that is analyzed to determine whether said cable diagnostic device can transition from said initial operating state to an active diagnostic state where said cable diagnostic module is available to analyze characteristics of said communication cable coupled to said port; and
a display having a user interface control screen that controls an operation of said cable diagnostic module, said user interface control screen being locked until said activation module determines that said cable diagnostic device can transition from said initial operating state to said active diagnostic state.

2. The system of claim 1, wherein said port is an Ethernet port.

3. The system of claim 1, wherein said port is coupled to said communication cable via an adapter.

4. The system of claim 1, wherein said activation module performs an authentication function.

5. The system of claim 1, wherein said activation module performs a licensing function.

6. The system of claim 1, wherein said authentication module is implemented in software.

7. A cable diagnostic device, comprising:
a port configured for coupling to a communication cable;
a physical layer device that is coupled to said port, said physical layer device including a cable diagnostic module for analyzing characteristics of said communication cable coupled to said port;
an activation module that is configured to control access by a user of said cable diagnostic device to said cable diagnostic module in said physical layer device, said control of said access effecting a limitation of use of said cable diagnostic module by said user; and
a display for displaying results of said analyzing to said user.

8. The system of claim 7, wherein said displayed result is whether a communication channel is active.

9. The system of claim 7, wherein said displayed result is a cable length.

10. The system of claim 7, wherein said displayed result is a cable type.

11. The system of claim 7, wherein said displayed result is an existence or a location of a cable fault.

12. The system of claim 7, wherein said port is an Ethernet port.

13. The system of claim 7, wherein said port is coupled to said communication cable via an adapter.

14. The system of claim 7, wherein said activation module performs an authentication function.

15. The system of claim 7, wherein said activation module performs a licensing function.

16. A method in a diagnostic device having a physical layer device, said diagnostic device having an initial operating state that prevents operation of a diagnostic module in said physical layer device that analyzes a communication channel coupled to a port in said diagnostic device, the method comprising:
receiving activation information in said diagnostic device;
transitioning based on said received activation information, said diagnostic device from said initial operating state to an active diagnostic state where said diagnostic module is available to analyze characteristics of said communication channel coupled to said port;
diagnosing, by said activated diagnostic module during said active diagnostic state, one or more parameters of said port; and
displaying, in a display of said cable diagnostic device, information based on said diagnosis.

17. The method of claim 16, wherein said displaying comprises displaying a communication channel characteristics.

18. The method of claim 16, wherein said displaying comprises displaying data testing results.

19. The method of claim 16, wherein said displaying comprises displaying traffic testing results.

20. The method of claim 16, wherein said displaying comprises displaying packet testing results.

21. The method of claim 16, wherein said displaying comprises displaying bit testing results.
